(19) United States
(12) Patent Application Publication
(10) Pub. No.: US 2007/0026150 A1
(43) Pub. Date: Feb. 1, 2007

(54) Substrate processing system

(76) Inventors: Takao Horiuchi, Tokyo (JP); Azumi Horiuchi, Palo Alto, CA (US); Hiroaki Ogamino, Tokyo (JP); Yasuhiro Niimura, Tokyo (JP); Hiroshi Hattori, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 10/559,669

(22) PCT Filed: Jun. 30, 2004
(86) PCT No.: PCT/JP04/09577

§ 371 Date: Dec. 6, 2005

(30) Foreign Application Priority Data
Jul. 4, 2003 (JP) 2003-191756

(51) Int. Cl. C23C 16/00; H01L 21/302

(52) U.S. Cl. 427/249.8; 438/726; 427/248.1

(57) ABSTRACT

A substrate processing system is provided, which efficiently utilizes reactive substances or carrier gases necessary for the surface processing of a substrate, simplifies equipment for the gas transfer and effects energy saving. This system comprises a gas supply source 12 for supplying a process gas containing a reactive substance, a reservoir tank 14 connected to the gas supply source 12 for reserving the process gas, a reactor 10 for exposing a substrate placed therein to the process gas, a first circulation pipe 38 for introducing the process gas inside the reactor 10 into the reservoir tank 14, a second circulation pipe 42 for introducing at least part of the process gas in the reservoir tank 14 into the reactor 10, and a flow regulating valve 44 disposed in the second circulation pipe 42 for regulating the amount of process gas to be introduced into the reactor 10.

### TECHNICAL FIELD

This invention relates to a substrate processing system and particularly to a substrate processing system for processing the surface of the substrate which is exposed to a reactive substance.

### BACKGROUND ART

Conventionally, in a substrate surface processing method using gases, for example, a CVD (Chemical Vapor Deposition), the surface of a substrate is exposed to a process gas containing a reactive substance for a relatively long time for processing, such as doping.

In the case there is no change of properties of the process gas after reaction, or the process gas is reusable irrespective of its property change, it is attempted to reuse the process gas. Such reuse of the process gas is favorable in terms of reducing harmful effects on the substrate itself or on human bodies or environments as well as in terms of cost reduction.

Also, a technique of reusing exhaust gas as a sealing gas for sealing the shaft of a vacuum pump is known (See Patent Document 1, for example), but this technique is insufficient in terms of effective utilization of a reactive substance contained in the gas. Further, a semiconductor manufacturing system is also known in which a gas discharged from a vacuum chamber is recycled to the vacuum chamber (See Patent Document 2, for example). This system has a problem that it is unable to handle a case the gas flow is intermittent, although it is able to handle a process in which a fixed amount of gas flow continues.

[Patent Document 1]

JP-A-2000-9037

[Patent Document 2]

JP-A-Hei 9-251981

In view of the foregoing problems in the prior art, it is an object of the invention to provide a substrate processing system which efficiently utilizes reactive substances or carrier gases necessary for processing the surface of a substrate, simplifies equipment for gas transfer and effects energy saving.

### DISCLOSURE OF INVENTION

In order to solve the foregoing problems in the prior art, a first embodiment of the invention is a substrate processing system which comprises: a gas supply source for supplying a process gas containing a reactive substance; a reservoir tank connected to the gas supply source for reserving the process gas; a reactor for exposing a substrate placed therein to the process gas; a first circulation pipe for introducing the process gas inside the reactor into the reservoir tank; a second circulation pipe for introducing at least part of the process gas in the reservoir tank into the reactor; and a flow regulating valve disposed in the second circulation pipe for regulating the amount of process gas to be introduced into the reactor. Here, the term “reactive” means not only chemical reactions but also phenomena in which the surface of a substrate changes its condition from the original one due to adhering of a substance or the like.

Since in such a construction, the process gas containing a reactive substance required to process the surface of a substrate can be circulated, the process gas can be reused efficiently. Also, equipment for gas transfer can be simplified and energy saving can be effected. Further, since the discharged gas is temporarily reserved in a reservoir tank and any amount of gas can be reused as required, so that the substrate processing system according to an embodiment of the present invention is able to handle the case the gas flow is intermittent.

One preferred embodiment of the invention is a substrate processing system further comprising a pump for drawing the process gas from the reactor and then introducing the drawn process gas into the reservoir tank through the first circulation pipe.

According to the invention as described above, a process gas containing a reactive substance required to process the surface of a substrate can be circulated, so that the process gas can be reused efficiently. Also, equipment for gas transfer can be simplified and energy saving can be effected.

This application is based on Japanese patent applications, No. 2003-191756 filed in Japan on Jul. 4, 2003, which is entirely incorporated herein by reference.

This invention will be more completely understood through the following detailed description. Additional application ranges of this invention will become clearer through the following detailed description. However, specific examples in the detailed explanation are preferable embodiments of the invention cited for the purpose of explanation only. For those skilled in the art, it is apparent that various changes and modifications can be made within the scope and spirit of the invention.

The applicant has no intention of dedicating to the public any of the described embodiments. Of the disclosed modifications and alternatives, those which may not be literally covered in what is claimed shall be part of the invention under the doctrine of equivalent.

### BRIEF DESCRIPTION OF DRAWINGS

FIG. 1 is a schematic diagram, illustrating the overall construction of a substrate processing system according to one embodiment of the invention.

### BEST MODE FOR CARRYING OUT THE INVENTION

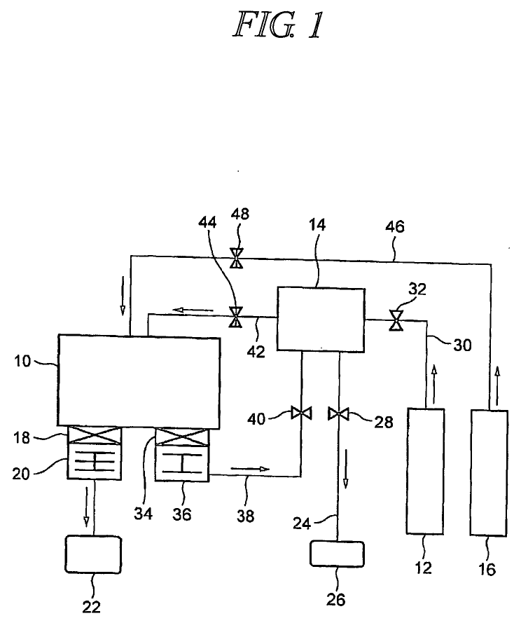

Now, an embodiment of the substrate processing system according to the invention is described in detail with reference to FIG. 1. FIG. 1 is a schematic diagram, illustrating the overall construction of a substrate processing system according to one embodiment of the invention. As shown in FIG. 1, the substrate processing system according to this embodiment comprises: a reactor 10 in which a substrate to be processed is placed; a first gas supply source 12 for supplying a first process gas containing a reactive substance to the reactor 10; a reservoir tank 14 connected to the first gas supply source 12; a second gas supply source 16 for supplying a second process gas to the reactor 10; a turbo-molecular pump 20 connected to the reactor 10 through a valve 18; and a dry pump 22 disposed downstream of the turbo-molecular pump 20.

The dry pump 26 is connected to the reservoir tank 14 through a pipe 24, and reduces a pressure within the reservoir tank 14. A valve 28 is disposed in the pipe 24 connecting the reservoir tank 14 and dry pump 26. Also, a valve 32 is disposed in a pipe 30 which connects the reservoir tank 14 and first gas supply source 12.

Also, a pressure pump 36 is connected to the reactor 10 through a valve 34. The pressure pump 36 is connected to the reservoir tank 14 through (a first) circulation pipe 38 in which a valve 40 is disposed. Also, the reservoir tank 14 is connected to the reactor 10 through (a second) circulation pipe 42 and in the circulation pipe 42 in which a flow regulating valve 44 for regulating the amount of first process gas to be introduced into the reactor 10 is disposed. The process gas inside the reactor 10 is also introduced into the reservoir tank 14 through the circulation pipe 38 and at least part of the process gas inside of the reservoir tank 14 is introduced into the reactor 10 through the circulation pipe 42. Further, the second gas supply source 16 is connected to the reactor 10 through a pipe 46, in which a flow regulating valve 48 for regulating the amount of second process gas to be introduced into the reactor 10 is disposed.

Now, a method of processing a substrate using the substrate processing system of the foregoing construction will be described. First, the valve 32 between the first gas supply source 12 and reservoir tank 14 and the valve 28 between the dry pump 26 and reservoir tank 14 are opened and the flow regulating valve 44 between the reservoir tank 14 and reactor 10 and the valve 40 between the pressure pump 36 and reservoir tank 14 are closed. Under this condition, the dry pump 21 is driven to reduce the pressure inside of the reservoir tank 14 to a given value Pr and the first process gas is then introduced and reserved in the reservoir tank 14 from the first gas supply source 12.

In this embodiment, the dry pump 26 is used to reduce the pressure inside of the reservoir tank 14. However, the turbo-molecular pump 20 and dry pump 22 may be used in place of the dry pump 26 to reduce the pressure inside of the reservoir tank 14 while the valve 18 and flow regulating valve 44 or valves 18, 34, 40 are opened. Also, if the pressure in the first gas supply source (gas cylinder) 12 is sufficiently high, the first process gas can be introduced into the reservoir tank 14 without the use of either dry pumps 22, 26 or turbo-molecular pump 20. Although in this embodiment, a process gas containing a reactive substance is supplied from the first gas supply source 12, a carrier gas may be supplied from the first gas supply source 12 and this carrier gas and a reactive substance may be mixed together downstream of the first gas supply source 12 to form a first process gas.

Thereafter, the valve 18 disposed upstream of the turbo-molecular pump 20 is opened and the turbo-molecular pump 20 and dry pump 22 are driven to reduce the pressure inside of the reactor 10 to a value not higher than the internal pressure Pr in the reservoir tank 14. Then, the valve 18 is closed to form a tightly closed space inside of the reactor 10.

Under this condition, if the valve 34 disposed upstream of the pressure pump 36, the valve 40 between the pressure pump 36 and reservoir tank 14, and the flow regulating valve 44 between the reservoir tank 14 and reactor 10 are opened with the other valves closed, the first process gas in the reservoir tank 14 at a higher pressure flows into the reactor 10 at a lower pressure and thus the first process gas is introduced in the reactor 10. At this time, the opening of the flow regulating valve 44 is controlled to regulate the amount of the process gas to be introduced into the reactor 10.

The substrate placed inside of the reactor 10 is exposed to the first process gas introduced into the reactor 10, and a reactive substance contained in the first process gas adheres on the surface of the substrate (adhering process). Since a circulation system of the first process gas is defined by the reactor 10, pressure pump 36, circulation pipe 38, reservoir tank 14, and circulation pipe 42, when the pressure pump 36 is driven to generate a pressure difference between the reactor 10 and reservoir tank 14, the first process gas can be circulated continuously. At this time, the valve 40 may be opened and closed to intermittently circulate the first process gas.

Although, in this embodiment, the first process gas is circulated using the pressure pump 36, it may be circulated using a circulation mechanism other than this pump. Also, an elimination device (for example, a filter) for eliminating unfavorable substances (such as condensates) in the process gas may be provided in the circulation pipe 38 or 42.

In this embodiment as described above, the first process gas from the first gas supply source 12 is reused through the foregoing circulation system. Therefore, a process gas can be reused efficiently, equipment for the gas transfer can be simplified and energy saving can be effected.

When reuse of the first process gas has reached to a limit or when the property of the first process gas has changed to the one unsuited for reuse for some reason, the valve 28 between the dry pump 26 and reservoir tank 14 is opened and the dry pump 26 is driven to discharge the process gas to the outside.

On the other hand, when the second process gas is used, the second process gas is introduced into the reactor 10 from the second gas supply source 16 through the flow regulating valve 48, for the reaction in the reactor 10. Thereafter, the flow regulating valve 48 is closed and the valve 18 disposed upstream of the turbo-molecular pump 20 is opened, to drive the turbo-molecular pump 20 and dry pump 22, so that the second process gas after reaction is discharged outside the system after passing through the elimination device (not shown).

After completion of a series of processings, the substrate processed is removed from the reactor 10, a next substrate is placed inside the reactor 10, and the foregoing procedure is repeated. The substrates may be loaded in the reactor 10 one by one or in the form of a batch.

Although, in this embodiment, an example has been described in which a first gas supply source 12 and a second gas supply source 16 are provided, only the first gas supply source 12 may be provided or multiple kinds of gas supply sources may be provided. Likewise, a reservoir tank, circulation pipes and the number of pumps are not limited to those in the drawings, and various measuring instruments and control devices necessary for the operations of the substrate processing system may additionally be provided as required.

The invention is suitably applied to Atomic Layer Deposition. In this method, the surface of a substrate is exposed to a reactive substance to form an extremely low profile (thin) layer and this procedure is repeated to process the surface of the substrate. According to the Atomic Layer Deposition, some tens to hundreds of extremely low profile (thin) layers each having a thickness in order of a few atoms (nanometers) can be deposited on the surface of a substrate, allowing subtle and free adjustment of the film thickness. This Atomic Layer Deposition uses a large amount of gas containing a reactive substance, but in one reaction process, only a small amount of reactive substance adheres to the target region of the substrate and most of the reactive substance is left unreacted. According to the embodiment of the present invention, a gas containing an adequate amount of unreacted reactive substance can be utilized without being discharged directly to the outside. Therefore, wasting of reactive substances or carrier gases is prevented, a size increase in equipment such as pump devices for the gas transfer can be avoided and energy consumption is kept in check. In such an embodiment, a plurality of film-forming gases are used as a first process gas. For example, in the case a film of silicon nitride is formed, a silane-based gas and an ammonia-based gas are supplied simultaneously or alternately. When they are supplied alternately, another reservoir is preferably provided.

Regarding a second process gas, one film-forming gas may be introduced into a reactor and mixed with a first process gas in the reservoir tank to adjust the concentration of the mixed gas, or a halogen-based cleaning gas may be supplied for cleaning the reactor 10 which requires no circulation after formation of a film. In particular, in the case reaction of the film-forming gas and the cleaning gas will generate by-products, it is effective to supply the second process gas (cleaning gas) such that it bypasses the reservoir tank.

Although an embodiment of the invention is described above, the present invention is not limited to the foregoing embodiment, but may be carried out otherwise in various ways within the scope of the concept of the invention.

Description of Reference Numerals

10: reactor
12: first gas supply source
14: reservoir tank
16: second gas supply source
18, 28, 32, 34, 40: valve
20: turbo-molecular pump
22, 26: dry pump
24, 30, 46: pipe
36: pressure pump
38: first circulation pipe
42: second circulation pump
44, 48: flow regulating valve

1. A substrate processing system comprising:
a gas supply source for supplying a process gas containing a reactive substance;
a reservoir tank connected to said gas supply source for reserving said process gas;
a reactor for exposing a substrate placed therein to said process gas;
a first circulation pipe for introducing the process gas inside said reactor into said reservoir tank;
a second circulation pipe for introducing at least part of the process gas in said reservoir tank into said reactor; and
a flow regulating valve disposed in said second circulation pipe for regulating the amount of process gas to be introduced into said reactor.

2. The substrate processing system of claim 1, further comprising a pump for drawing said process gas from said reactor and introducing it into said reservoir tank through said first circulation pipe.

3. The substrate processing system of claim 1, further comprising a second gas supply source for supplying a second process gas to said reactor such that the second process gas bypasses said reservoir tank, said second process gas containing a reactive substance different from that contained in said first process gas.

4. The substrate processing system of claim 2, further comprising a second gas supply source for supplying a second process gas to said reactor such that the second process gas bypasses said reservoir tank, said second process gas containing a reactive substance different from that contained in said first process gas.
